(19) United States
(12) Patent Application Publication
(10) Pub. No.: US 2005/0138534 A1
(43) Pub. Date: Jun. 23, 2005

(54) Maximum likelihood encoding apparatus, maximum likelihood encoding method, program and reproduction apparatus

(76) Inventors: Takeshi Nakajima, Nara (JP); Keisuke Fujimoto, Osaka (JP); Youichi Ogura, Ehime (JP)

Correspondence Address: MARK D. SARALINO (GENERAL);RENNER, OTTO, BOISELLE & SKLAR, LLP, 1621 EUCLID AVENUE, NINETEENTH FLOOR, CLEVELAND, OH, 44115-2191, US

(21) Appl. No.: 10/973,127

(22) Filed: Oct. 26, 2004

(30) Foreign Application Priority Data
Oct. 27, 2003 (JP) 2003-365651

(51) Int. Cl. H03M 13/03

(52) U.S. Cl. 714/794

(57) ABSTRACT

A maximum likelihood encoding apparatus is provided, which is constructed to be compatible with a plurality of signals reproduced from a plurality of recording media having a plurality of types. The apparatus comprises a path metric value generation section for generating a plurality of path metric values corresponding to a recording medium having one of the plurality of types based on a type signal indicating the one of the plurality of types, and a path memory section for detecting digital information from a signal reproduced from the recording medium having the one of the plurality of types based on the plurality of path metric values.

This nonprovisional application claims priority under 35 U.S.C. §119(a) on Patent Application No. 2003-365651 filed in Japan on Oct. 27, 2003, the entire contents of which are hereby incorporated by reference.

### BACKGROUND OF THE INVENTION

1. Field of the Invention

The present invention relates to a maximum likelihood encoding apparatus compatible with a plurality of signals reproduced from a plurality of types of recording media, a method and program for maximum likelihood encoding a plurality of reproduced signals using the apparatus, and a reproduction apparatus comprising the apparatus. More particularly, the present invention relates to, for example, a reproduction apparatus for detecting original digital information from a high-density recording medium using partial response maximum likelihood (PRML) signal processing technology.

2. Description of the Related Art

Original digital information recorded on a recording medium with high-density is decoded by, for example, PRML signal processing, which is a combination of partial response equalization (hereinafter referred to as PR equalization) and Viterbi encoding.

When data is recorded on a recording medium with high-density, intercode interference occurs due to the frequency characteristics of a recording/reproduction system, resulting in a reduction in signal amplitude. PR equalization can give known intercode interference, thereby improving an S/N value more significantly than conventional Nyquist equalization. A state transition rule is determined from recorded codes based on the known intercode interference. Viterbi encoding can detect the most probable original digital information from a reproduced signal using the transition rule.

For example, Japanese Patent No. 3301691 (particularly, FIG. 2) discloses a digital information reproduction apparatus using PRML signal processing.

FIG. 16 shows a state transition diagram A. State transition indicated by the state transition diagram A can be obtained by applying PR1331 equalization to recorded codes whose minimum polarity reversal interval is 3 (e.g., 8-16 modulation for DVD, etc.).

FIG. 17 shows a trellis diagram A. The trellis diagram A can be obtained by extending state transition shown in the state transition diagram A in a time axis direction.

A trellis diagram A shows all possible state transitions. Square errors between expected values determined by PR equalization and reproduced signals are accumulated. A state transition having the smallest square error is selected to estimate original digital information. The Viterbi algorithm is commonly used as a technique for efficient estimation of original digital information.

The following expression 1 shows recurrence formulas in which the Viterbi algorithm is adapted to the state transition indicated by the state transition diagram A. The probability of each of a plurality of states is defined as a path metric Lₖ^{Sn} (k is an integer indicating time). The state transition of the state transition diagram A includes six states, so that n is an integer of 0 to 5.
Lₖ^{S0}=min[Lₖ₋₁^{S0}+(yₖ+4), Lₖ₋₁^{S5}+(yₖ+3)²]
Lₖ^{S1}=Lₖ^{S0}+(yₖ+3)²
Lₖ^{S2}=Lₖ₋₁^{S1}+(yₖ+0)²
Lₖ^{S5}=Lₖ₋₁^{S4}+(yₖ+0)²
Lₖ^{S4}=Lₖ₋₁^{S3}+(yₖ−3)²
Lₖ^{S3}=min[Lₖ₋₁^{S3}+(yₖ−4)², Lₖ₋₁^{S2}+(yₖ−3)²] (Expression 1)
where an operator min[xx, zz] is an operator which selects the smaller of xx and zz and a calculation (yₖ+E)² indicates a branch metric, in which E indicates an expected value determined by PR equalization.

One of the possible state transitions, which has a probable path metric value, is selected based on a probability Lₖ₋₁^{Sn} at time k−1 and a reproduced signal yₖ input at time k. The above-described selection step is performed for each time. If the selection results are tracked back, a unique state transition sequence (path) is found. Such a path is called a survival path. By referencing to expression 1, original digital information can be detected based on the state transition rule.

The transfer rates of apparatuses for recording media are increasing year by year. For example, in the field of optical discs, each manufacturer is trying to double the transfer rate of apparatuses. A DVD apparatus for personal computers (PC) achieves a high transfer rate (e.g., 16×). In this case, the channel clock reaches as high as 432 MHz.

It is very difficult to perform a calculation, such as expression 1, while achieving a high transfer rate at each time point. Therefore, it is considered that the calculation of expression 1 is performed once every two or more time points rather than every time point.

Japanese Laid-Open Publication No. 9-289457 (particularly, FIGS. 5 and 6) discloses a method for performing the calculation of expression 1 once every two or more time points.

FIG. 18 shows a trellis diagram B prepared by referencing state transition for two clock counts, i.e., from time k−2 to time k.

Expression 2 shows a path metric (probability) of each state transition sequence for two clock counts from time k−2 to time k.
Lₖ^{S0}=min[min[Lₖ₋₂^{S0}+(yₖ+4)², Lₖ₋₂^{S5}+(yₖ₋₁+3)²]+(yₖ+4)², Lₖ₋₂^{S4}+(yₖ₋₁+0)²+(yₖ+3)²]
Lₖ^{S1}=min[Lₖ₋₂^{S0}+(yₖ₋₁+4)², Lₖ₋₂^{S5}+(yₖ₋₁+3)²]+(yₖ+3)²
Lₖ^{S2}=Lₖ₋₂^{S0}+(yₖ₋₁+3)²+(yₖ+0)²
Lₖ^{S5}=Lₖ₋₂^{S3}+(yₖ₋₁−3)²+(yₖ+0)²
Lₖ^{S4}=min[Lₖ₋₂^{S3}+(yₖ₋₁−4)², Lₖ₋₂^{S2}+(yₖ₋₁−3)²]+(yₖ₋₃)²
Lₖ^{S3}=min[min[Lₖ₋₂^{S3}+(yₖ₋₁−4)², Lₖ₋₂^{S2}+(yₖ₋₁−3)²]+(yₖ−4)², Lₖ₋₂^{S1}+(yₖ₋₁+0)²+(yₖ−3)²] (Expression 2)

A path metric at time k may be selected based on a path metric value at time k−2 and an input reproduced signal yₖ and reproduced signal yₖ₋₁. The above-described selection is performed once every two time points. If the selection results are tracked back, original digital information can be similarly obtained based on the state transition rule. Therefore, the circuit can be operated at ½ the frequency of a channel clock.

While the transfer rates of apparatuses are increased, the number of types of optical discs compatible with apparatuses is also increased. CD is mainly used for music applications, while DVD is mainly used for video applications. The advent of the blue laser leads to the development of higher-recording density optical discs (e.g., Blu-rayDisc).

CD adopts EFM modulation while DVD adopts 8-16 modulation. An optical disc using blue laser adopts (1, 7) modulation. Thus, the recording density and the recorded code vary depending on the type of optical disc. Appropriate PRML processing is required for each optical disc type. Therefore, a reproduction apparatus needs to comprise Viterbi circuits which are compatible with the corresponding types of inserted optical discs. As a result, the circuit scale of the reproduction apparatus is increased, resulting in an increase in the cost of the reproduction apparatus.

Japanese Laid-Open Publication No. 11-41116 (particularly, FIGS. 3, 4, 6, 10, 11, 12, 19 and 20) discloses an apparatus which is compatible with a plurality of signals reproduced from a plurality of recording media having a plurality of types.

FIG. 19 shows the configuration of a Viterbi detection apparatus 1000 disclosed in Japanese Laid-Open Publication No. 11-41116.

The Viterbi detection apparatus 1000 comprises a branch metric generation circuit 1010, a first selector 1020, an ACS circuit 1030, and a second selector 1040, and a path memory circuit 1050.

The branch metric generation circuit 1010 generates three branch metric values (xᵢ+1)², xᵢ² and (xᵢ−1)² based on an input signal xᵢ.

The first selector 1020 selects a portion of the three branch metric values (xᵢ+1)², xᵢ² and (xᵢ−1)² based on whether an optical disc is of a two-state transition type or a four-state transition type. When an optical disc is of the two-state transition type, the first selector 1020 selects the branch metric value xᵢ². When an optical disc is of the four-state transition type, the first selector 1020 selects the branch metric values (xᵢ+1)² and (x−1)².

The ACS circuit 1030 generates four path metric values Pⱼ (j=0, 1, 2, 3) based on the branch metric values (xᵢ+1)², xᵢ² and (xᵢ−1)².

The second selector 1040 selects a portion of the four path metric values Pⱼ (j=0, 1, 2, 3) based on a type signal. When an optical disc is of the two-state transition type, the second selector 1040 selects the path metric values P₀ and P₃. When an optical disc is of the four-state transition type, the second selector 1040 selects the path metric values P₁ and P₂.

However, the branch metric generation circuit 1010 of the Viterbi detection apparatus 1000 generates a plurality of branch metric values corresponding to a two-state transition type recording medium and a four-state transition type recording medium. The ACS circuit 1030 of the Viterbi detection apparatus 1000 generates a plurality of path metric values corresponding to a two-state transition type recording medium and a four-state transition type recording medium. Therefore, it is necessary to generate a plurality of branch metric values corresponding to optical discs of types other than those indicated by the type signals and a plurality of path metric values corresponding to optical discs of types other than those indicated by the type signals.

Further, conventionally, high transfer rates have been achieved and Viterbi circuits have been improved to reduce the circuit scale. However, the transfer rate needs to be further improved and the circuit scale needs to be further reduced.

### SUMMARY OF THE INVENTION

According to an aspect of the present invention, a maximum likelihood encoding apparatus is provided, which is constructed to be compatible with a plurality of signals reproduced from a plurality of recording media having a plurality of types. The apparatus comprises a path metric value generation section for generating a plurality of path metric values corresponding to a recording medium having one of the plurality of types based on a type signal indicating the one of the plurality of types, and a path memory section for detecting digital information from a signal reproduced from the recording medium having the one of the plurality of types based on the plurality of path metric values.

In one embodiment of this invention, the path metric value generation section generates a plurality of path metric values at current time k based on a plurality of path metric values at time k−n where k is an integer and n is an integer of 1 or more.

In one embodiment of this invention, the maximum likelihood encoding apparatus further comprises a branch metric value generation section for generating a plurality of branch metric values from an expected value signal indicating an expected value and the signal reproduced from the recording medium having the one of the plurality of types. The path metric value generation section generates the plurality of path metric values based on the plurality of branch metric values and the type signal.

In one embodiment of this invention, the expected value signal is determined based on PR equalization characteristics. The branch metric value generation section comprises a difference value generation section for generating a difference value between the expected value and a reproduced value indicated by the signal reproduced from the recording medium having the one of the plurality of types, and a section for multiplying the difference value by a constant.

In one embodiment of this invention, the signal reproduced from the recording medium having the one of the plurality of types is subjected to maximum likelihood encoding by PR equalization satisfying:
h((2k−1)T/2)=a (k=−1)
h((2k−1)T/2)=b (k=0)
h((2k−1)T/2)=b (k=1)
h((2k−1)T/2)=a (k=2)
h((2k−1)T/2)=0 (k≠−1, 0, 1, 2)
where h(t) indicates an impulse response of a recording/reproduction system, a and b indicate arbitrary constants, and T indicates a cycle of a timing signal. The type signal indicates one of a type having a minimum polarity reversal interval of 2 and a type having a minimum polarity reversal interval of 3.

According to another aspect of the present invention, a maximum likelihood encoding apparatus is provided, which is constructed to be compatible with a plurality of signals reproduced from a plurality of recording media having a plurality of types. The apparatus comprises a branch metric value generation section for generating a plurality of branch metric values corresponding to a recording medium having one of the plurality of types based on a type signal indicating the one of the plurality of types, and a branch memory section for detecting digital information from a signal reproduced from the recording medium having the one of the plurality of types based on the plurality of branch metric values.

In one embodiment of this invention, the branch metric value generation section generates a plurality of branch metric values at current time k based on a plurality of path metric values at time k−n where k is an integer and n is an integer of 1 or more.

In one embodiment of this invention, the branch metric value generation section generates the plurality of branch metric values based on an expected value signal indicating an expected value and the recording medium having the one of the plurality of types. The maximum likelihood encoding apparatus further comprises a path metric value generation section for generating a plurality of path metric values based on the plurality of branch metric values and the type signal.

In one embodiment of this invention, the expected value signal is determined based on PR equalization characteristics. The branch metric value generation section comprises a difference value generation section for generating a difference value between the expected value and a reproduced value indicated by the signal reproduced from the recording medium having the one of the plurality of types, and a section for multiplying the difference value by a constant.

In one embodiment of this invention, the signal reproduced from the recording medium having the one of the plurality of types is subjected to maximum likelihood encoding by PR equalization satisfying:
h((2k−1)T/2)=a (k=−1)
h((2k−1)T/2)=b (k=0)
h((2k−1)T/2)=b (k=1)
h((2k−1)T/2)=a (k=2)
h((2k−1)T/2)=0 (k≠1, 0, 1, 2)
where h(t) indicates an impulse response of a recording/reproduction system, a and b indicate arbitrary constants, and T indicates a cycle of a timing signal. When one of the plurality of types has a minimum polarity reversal interval of 2, a=1 and b=2. When another of the plurality of types has a minimum polarity reversal interval of 3, a=3 and b=4.

According to another aspect of the present invention, a maximum likelihood encoding method is provided, in which an apparatus constructed to be compatible with a plurality of signals reproduced from a plurality of recording media having a plurality of types, is used for maximum likelihood encoding of the plurality of reproduced signals. The method comprises generating a plurality of path metric values corresponding to a recording medium having one of the plurality of types based on a type signal indicating the one of the plurality of types, and detecting digital information from a signal reproduced from the recording medium having the one of the plurality of types based on the plurality of path metric values.

According to another aspect of the present invention, a maximum likelihood encoding method is provided, in which an apparatus constructed to be compatible with a plurality of signals reproduced from a plurality of recording media having a plurality of types, is used for maximum likelihood encoding of the plurality of reproduced signals. The method comprises generating a plurality of branch metric values corresponding to a recording medium having one of the plurality of types based on a type signal indicating the one of the plurality of types, and detecting digital information from a signal reproduced from the recording medium having the one of the plurality of types based on the plurality of branch metric values.

According to another aspect of the present invention, a program is provided for causing an apparatus constructed to be compatible with a plurality of signals reproduced from a plurality of recording media having a plurality of types to perform a maximum likelihood encoding process for maximum likelihood encoding of the plurality of reproduced signals. The maximum likelihood encoding process comprises generating a plurality of path metric values corresponding to a recording medium having one of the plurality of types based on a type signal indicating the one of the plurality of types, and detecting digital information from a signal reproduced from the recording medium having the one of the plurality of types based on the plurality of path metric values.

According to another aspect of the present invention, a program is provided for causing an apparatus constructed to be compatible with a plurality of signals reproduced from a plurality of recording media having a plurality of types to perform a maximum likelihood encoding process for maximum likelihood encoding of the plurality of reproduced signals. The maximum likelihood encoding process comprises generating a plurality of branch metric values corresponding to a recording medium having one of the plurality of types based on a type signal indicating the one of the plurality of types, and detecting digital information from a signal reproduced from the recording medium having the one of the plurality of types based on the plurality of branch metric values.

According to another aspect of the present invention, a reproduction apparatus is provided, which comprises an access section constructed to be able to access a plurality of recording media having a plurality of types, and a maximum likelihood encoding section constructed to be compatible with a plurality of signals reproduced from the plurality of recording media having the plurality of types. The maximum likelihood encoding section comprises a path metric value generation section for generating a plurality of path metric values corresponding to a recording medium having one of the plurality of types based on a type signal indicating the one of the plurality of types, and a path memory section for detecting digital information from a signal reproduced from the recording medium having the one of the plurality of types based on the plurality of path metric values.

According to another aspect of the present invention, a reproduction apparatus is provided, which comprises an access section constructed to be able to access a plurality of recording media having a plurality of types, and a maximum likelihood encoding section constructed to be compatible with a plurality of signals reproduced from the plurality of recording media having the plurality of types. The maximum likelihood encoding section comprises a path metric value generation section for generating a plurality of branch metric values corresponding to a recording medium having one of the plurality of types based on a type signal indicating the one of the plurality of types, and a path memory section for detecting digital information from a signal reproduced from the recording medium having the one of the plurality of types based on the plurality of branch metric values.

According to the maximum likelihood encoding apparatus, the maximum likelihood encoding method, the program and the reproduction apparatus of the present invention, a maximum likelihood encoding apparatus constructed to be compatible with a plurality of signals reproduced from a plurality of recording media having a plurality of types is used to generate a plurality of path metric values corresponding to a type of recording medium. Therefore, a plurality of path metric values corresponding to a plurality of types of recording media are not generated. As a result, an optical disc can be driven at a high transfer rate, and the circuit scale can be reduced.

Further, according to the maximum likelihood encoding apparatus, the maximum likelihood encoding method, the program and the reproduction apparatus of the present invention, a maximum likelihood encoding apparatus constructed to be compatible with a plurality of signals reproduced from a plurality of recording media having a plurality of types is used to generate a plurality of branch metric values corresponding to a type of recording medium. Therefore, a plurality of branch metric values corresponding to a plurality of types of recording media are not generated. As a result, an optical disc can be driven at a high transfer rate, and the circuit scale can be reduced.

Furthermore, according to the maximum likelihood encoding apparatus, the maximum likelihood encoding method, the program and the reproduction apparatus of the present invention, a maximum likelihood encoding apparatus constructed to be compatible with a plurality of signals reproduced from a plurality of recording media having a plurality of types can be operated at 1/n frequency of a channel clock. In the apparatus, a circuit(s) can be shared for different recorded codes. By performing branch metric calculations only by addition and subtraction, the circuit scale can be reduced. As a result, the cost of the apparatus can be significantly reduced.

Thus, the invention described herein makes possible the advantages of providing a maximum likelihood encoding apparatus having a high operating speed and a small circuit scale, a method and program for maximum likelihood encoding a plurality of reproduced signal using the apparatus, and a reproduction apparatus comprising the apparatus.

These and other advantages of the present invention will become apparent to those skilled in the art upon reading and understanding the following detailed description with reference to the accompanying figures.

### BRIEF DESCRIPTION OF THE DRAWINGS

FIG. 1 is a diagram showing a configuration of a digital information reproduction apparatus according to the present invention.

FIG. 2 is a diagram showing a configuration of a Viterbi circuit.

FIG. 3 is a diagram showing a configuration of the Viterbi circuit of FIG. 2 in more detail.

FIG. 4 is a diagram showing a configuration of a sub-branch metric calculation circuit.

FIG. 5 is a diagram showing a configuration of another sub-branch metric calculation circuit.

FIG. 6 is a diagram showing a configuration of a block of FIG. 3.

FIG. 7 is a diagram showing a configuration of an ACS circuit of FIG. 3.

FIG. 8 is a diagram showing configurations of blocks of FIG. 7.

FIG. 9 is a diagram showing a configuration of a path metric subtraction circuit of FIG. 7.

FIG. 10 is a diagram showing configurations of a first path selection circuit and a second path selection circuit of FIG. 7.

FIG. 11 is a diagram showing a configuration of a path memory circuit of FIG. 3.

FIG. 12 is a diagram showing a configuration of the sub-memory circuit of FIG. 11.

FIG. 13 is a diagram showing a state transition diagram C obtained by applying PR1221 equalization to a recorded code having a minimum polarity reversal interval of 2. FIG. 14 is a trellis diagram corresponding to the state transition diagram of FIG. 13.

FIG. 15 is a diagram showing a configuration of a sub-branch metric calculation circuit.

FIG. 16 is a state transition diagram.

FIG. 17 is another trellis diagram.

FIG. 18 is another trellis diagram prepared by referencing state transition for two clock counts, i.e., from time k−2 to time k.

FIG. 19 is a diagram showing the configuration of a conventional Viterbi detection apparatus.

### DESCRIPTION OF THE PREFERRED EMBODIMENTS

Hereinafter, the present invention will be described by way of illustrative examples with reference to the accompanying drawings.

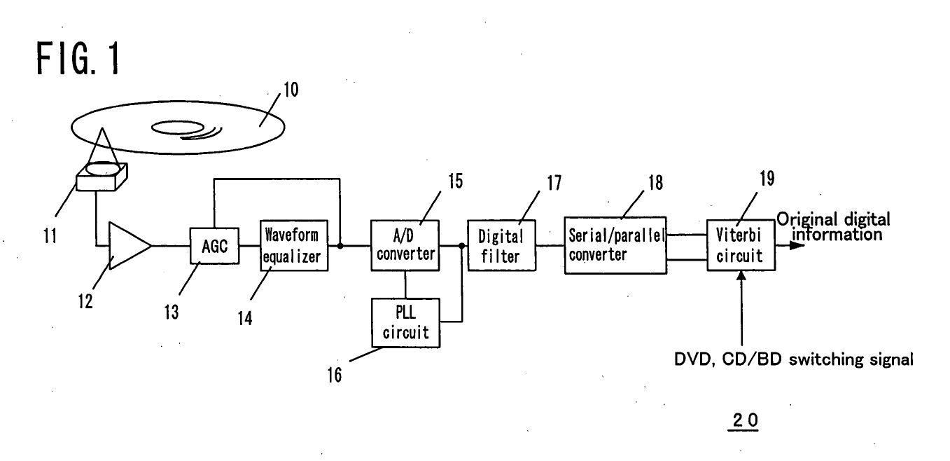

FIG. 1 shows a configuration of a digital information reproduction apparatus 20 according to the present invention. The digital information reproduction apparatus 20 is constructed to load a recording medium 10. Examples of the recording medium 10 include CD, DVD and BD.

The digital information reproduction apparatus 20 comprises an optical head 11, a preamplifier 12, an AGC (automatic gain controller) 13, a waveform equalizer 14, and A/D converter 15, a PLL circuit 16, a digital filter 17, a serial/parallel converter 18, and a Viterbi circuit 19.

The optical head 11 is constructed to be able to access a plurality of recording media having a plurality of types. The optical head 11 irradiates the recording medium 10 with laser light. The optical head 11 converts information on the recording medium 10 into an electrical signal (reproduced signal) based on laser light reflected from the recording medium 10. The preamplifier 12 amplifies the reproduced signal. The amplified reproduced signal is input via the AGC 13 to the waveform equalizer 14 to shape a waveform. The A/D converter 15 quantizes the waveform-shaped reproduced signal with reference to a clock reproduced by the PLL circuit 16. The quantized reproduced signal is input to the digital filter 17 which shapes the waveform thereof to obtain predetermined PR equalization characteristics. The PR equalized reproduced signal is input to the serial/parallel converter 18 which outputs n reproduced signals (n is an integer of 2 or more) simultaneously. The parallel reproduced signals are input to the Viterbi circuit 19. Further, a type signal (e.g., a DVD, CD/BD switching signal) is input to the Viterbi circuit 19. The type signal indicates one of a plurality of types.

The Viterbi circuit 19 is constructed to be compatible with a plurality of signals reproduced from a plurality of recording media having a plurality of types. The Viterbi circuit 19 detects original digital information from the parallel reproduced signal. The Viterbi circuit 19 is operated at 1/n the frequency of a channel clock. The Viterbi circuit 19 performs parallel processing, thereby making it possible obtain the high-transfer-rate digital information reproduction apparatus 20.

For example, the Viterbi circuit 19 is compatible with a state transition obtained by applying PR1221 equalization to a recorded code having a minimum polarity reversal interval of 2, and a state transition obtained by applying PR3443 equalization to a recorded code having a minimum polarity reversal interval of 3.

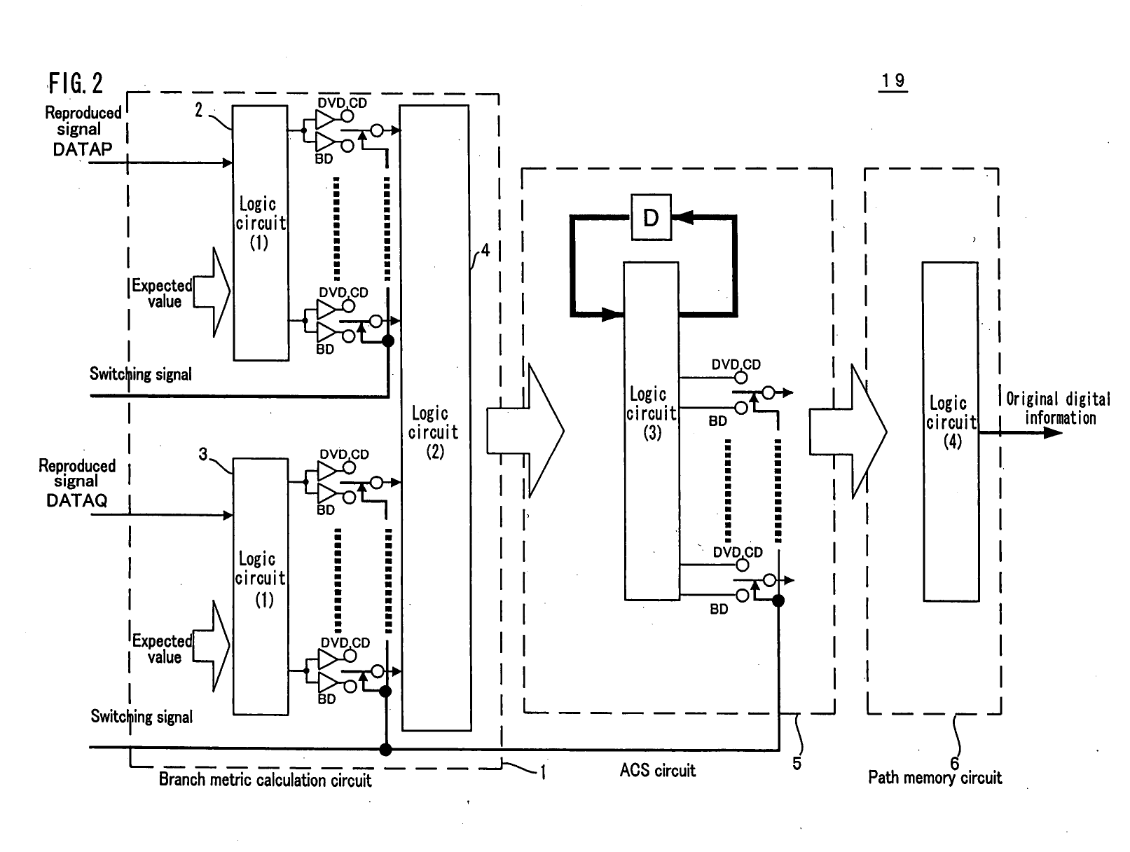

FIG. 2 shows a configuration of the Viterbi circuit 19.

The Viterbi circuit 19 comprises a branch metric calculation circuit 1, an ACS circuit 5, and a path memory circuit 6. The Viterbi circuit 19 obtains a current path metric at time k based on a path metric at time k−2, are produced signal yₖ (reproduced signal DATAP) and a reproduced signal yₖ₋₁ (reproduced signal DATAQ) to select a most probable state transition among two or three state transitions.

The waveforms of the reproduced signal yₖ and the reproduced signal yₖ₋₁ are shaped in accordance with PR equalization satisfying the following expression:
h((2k−1)T/2)=a (k=−1)
h((2k−1)T/2)=b (k=0)
h((2k−1)T/2)=b (k=1)
h((2k−1)T/2)=a (k=2)
h((2k−1)T/2)=0 (k≠1, 0, 1, 2)
where h(t) indicates an impulse response of a recording/reproduction system, where a and b are arbitrary constants, and T indicates a cycle of a timing signal. When the type of a recording medium is a type having a minimum polarity reversal interval of 2, a=1 and b=2. When the type of a recording medium is a type having a minimum polarity reversal interval of 3, a=3 and b=4.

The branch metric calculation circuit 1 generates a plurality of branch metric values corresponding to a type of recording medium based on a type signal. The generated branch metric values are input to the ACS circuit 5.

The ACS circuit 5 generates a plurality of path metric values corresponding to a type of recording medium based on a plurality of branch metric values and a type signal. The generated path metric values are input to the path memory circuit 6.

The path memory circuit 6 detects digital information from a signal reproduced from a type of recording medium based on a plurality of path metric values.

The branch metric calculation circuit 1 comprises a sub-branch metric calculation circuit 2 for processing the reproduced signal yₖ₋₁ at time k−1, a sub-branch metric calculation circuit 3 for processing the reproduced signal yₖ at time k, and a block 4 for adding a branch metric at time k with a branch metric at time k−1.

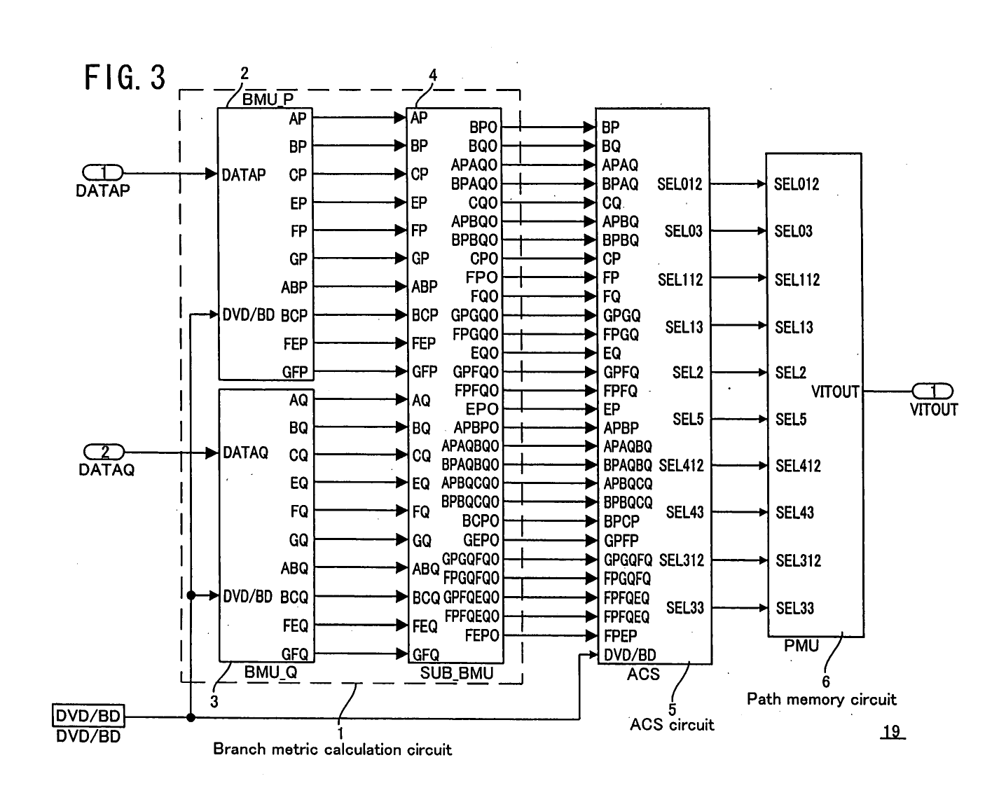

FIG. 3 shows the configuration of the Viterbi circuit 19 in more detail. In FIG. 3, the same components as those of the Viterbi circuit 19 of FIG. 2 are referenced with the same reference numerals and will not be explained.

The sub-branch metric calculation circuit 2 receives the reproduced signal yₖ₋₁ (reproduced signal DATAP) at time k−1. The sub-branch metric calculation circuit 3 receives the reproduced signal yₖ (reproduced signal DATAQ) at time k. The block 4 adds the branch metric at time k with the branch metric at time k−1. The branch metric calculation circuit 1 generates a plurality of branch metric values, which are in turn input to the ACS circuit 5.

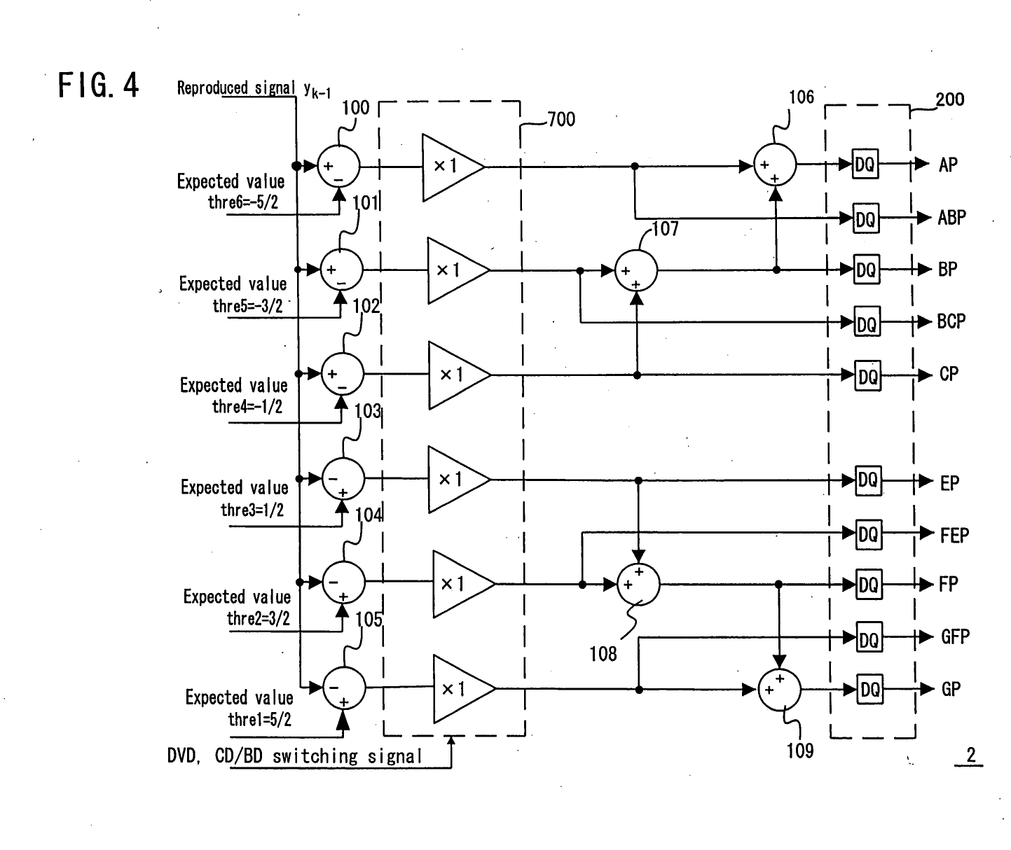

FIG. 4 shows a configuration of the sub-branch metric calculation circuit 2. The sub-branch metric calculation circuit 2 comprises subtractors 100 to 105, a coefficient setting block 700, adders 106 to 109, and a block 200.

Each of the subtractors 100 to 105 receives the reproduced signal yₖ₋₁ and an expected value signal indicating an expected value. Each of the subtractors 100 to 105 generates a difference value between a reproduced value indicated by the reproduced signal yₖ₋₁ and the expected value.

The coefficient setting block 700 multiplies a difference value by a constant. The constant is determined based on the DVD, CD/BD switching signal.

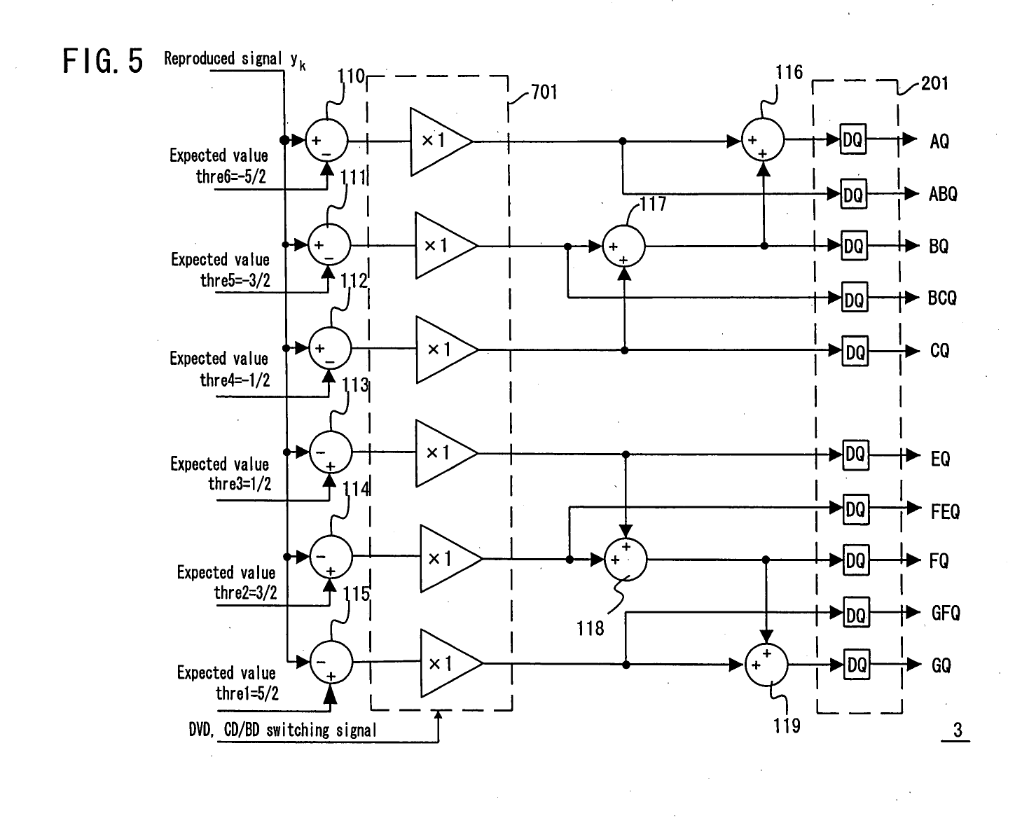

FIG. 5 shows a configuration of the sub-branch metric calculation circuit 3. The sub-branch metric calculation circuit 3 comprises subtractors 110 to 115, a coefficient setting block 701, adders 116 to 119, and a block 201.

Each of the subtractors 110 to 115 receives the reproduced signal yₖ and an expected value signal indicating an expected value. Each of the subtractors 110 to 115 generates a difference value between a reproduced value indicated by the reproduced signal yₖ₋₁ and the expected value.

The coefficient setting block 701 multiplies a difference value by a constant. The constant is determined based on the DVD, CD/BD switching signal.

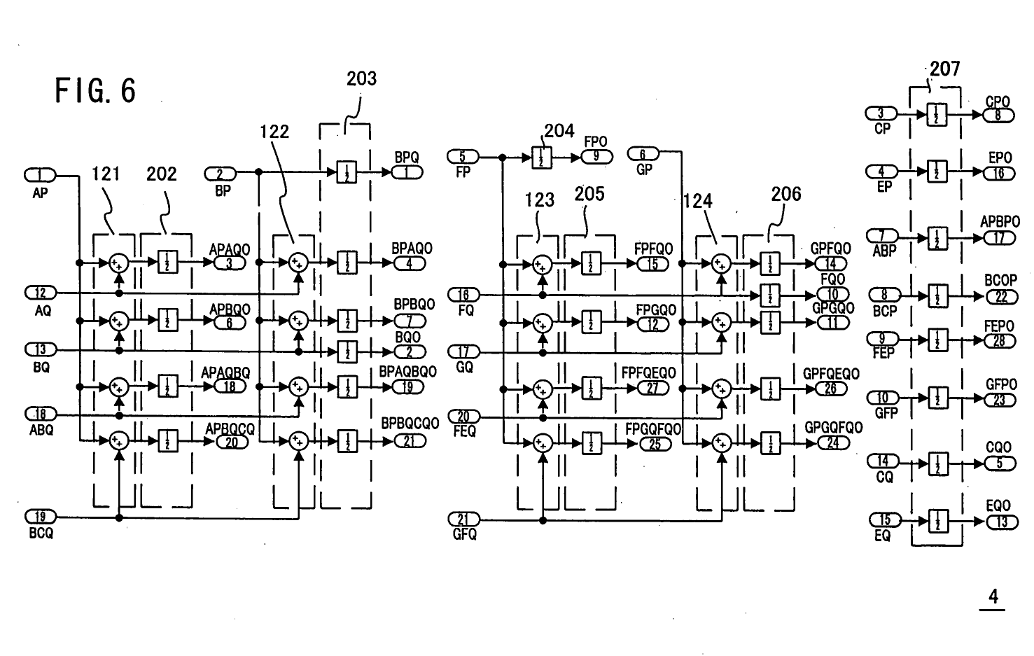

FIG. 6 shows a configuration of the block 4. As described above, the block 4 is constructed to add the branch metric at time k with the branch metric at time k−1.

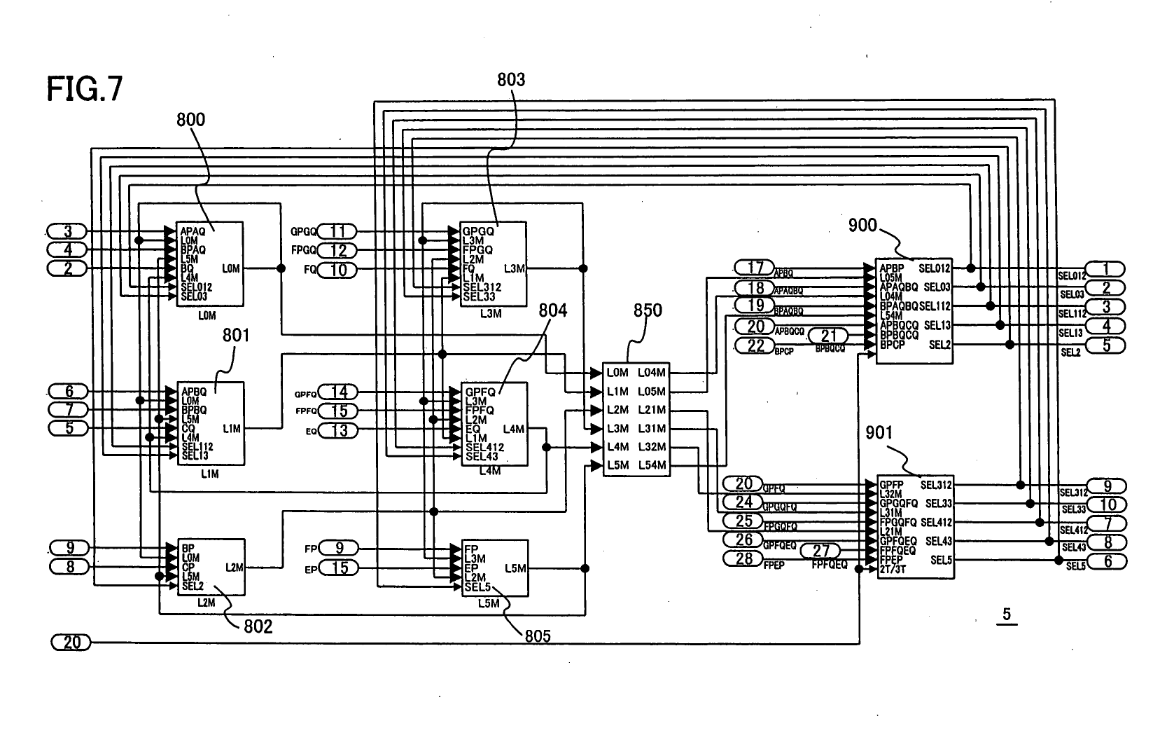

FIG. 7 shows a configuration of the ACS circuit 5. The ACS circuit 5 comprises blocks 800 to 805 for calculating path metrics of Lₖ^{S0} to Lₖ^{S5}, a path metric subtraction circuit 850, a first path selection circuit 900, and a second path selection circuit 901. The ACS circuit 5 performs calculations indicated by expressions 8 to 19 described below.

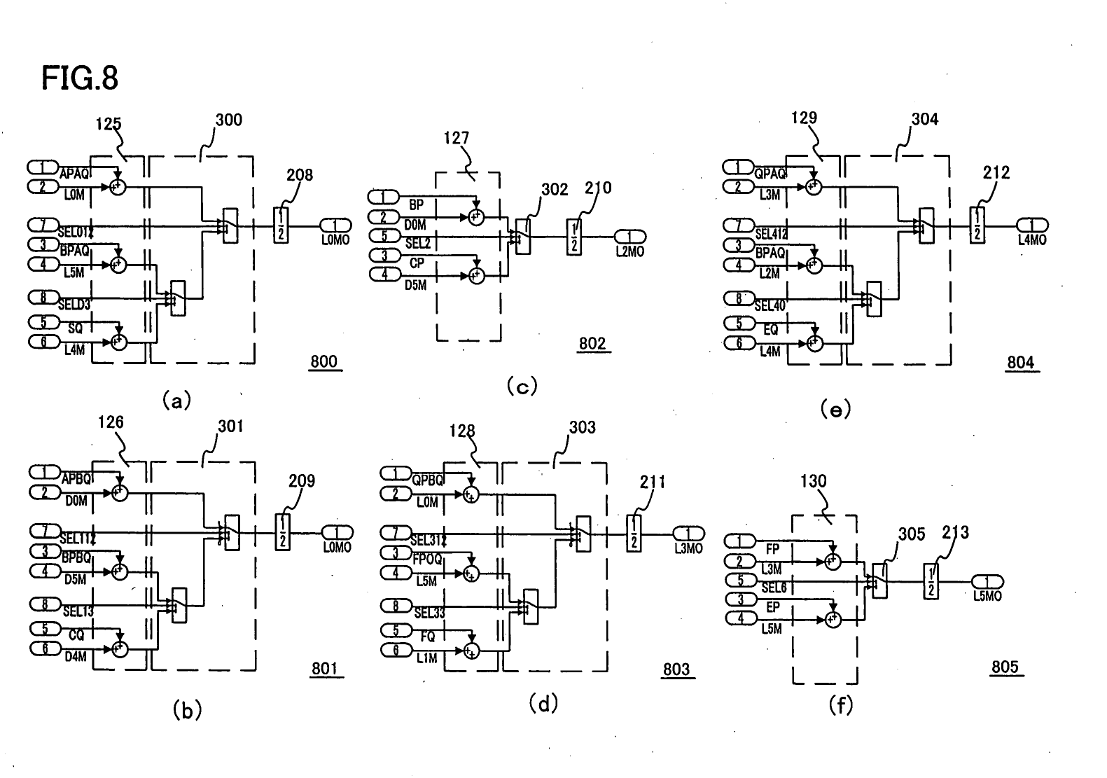

FIG. 8 shows configurations of the blocks 800 to 805. The block 800 performs a calculation indicated by expression 9. The block 801 performs a calculation indicated by expression 11. The block 802 performs a calculation indicated by expression 13. The block 803 performs a calculation indicated by expression 15. The block 804 performs a calculation indicated by expression 17. The block 805 performs a calculation indicated by expression 19.

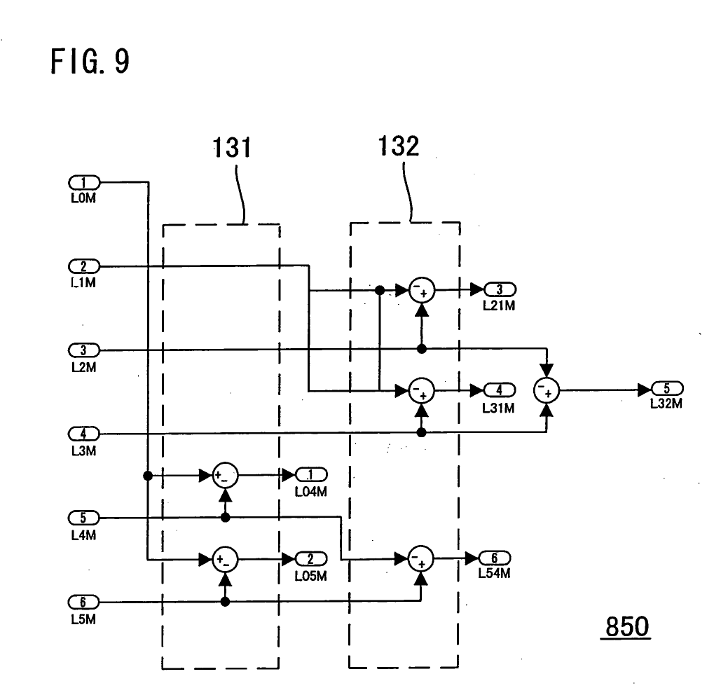

FIG. 9 shows a configuration of the path metric subtraction circuit 850.

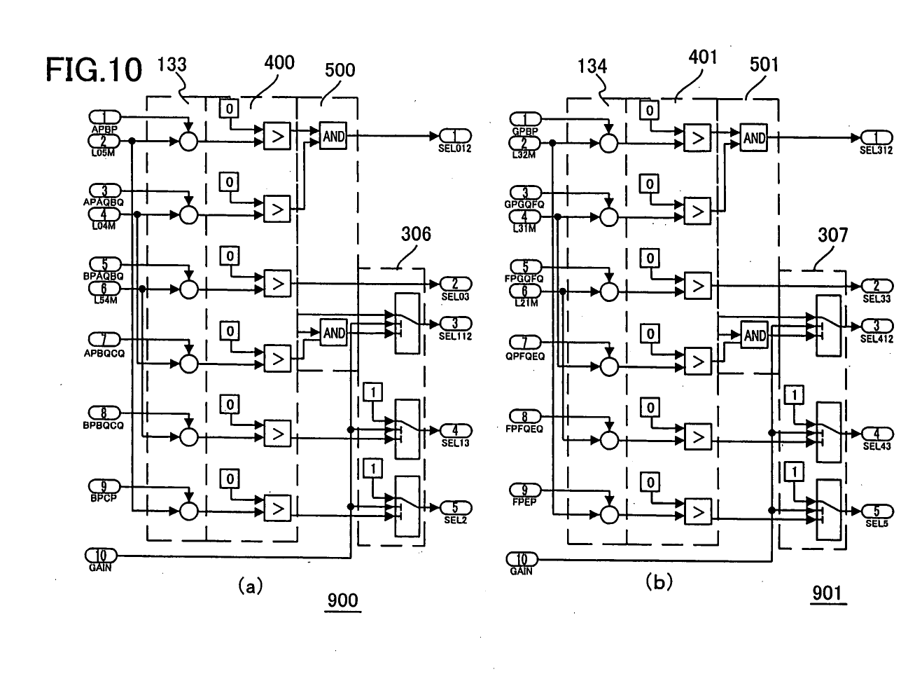

FIG. 10 shows configurations of the first path selection circuit 900 and the second path selection circuit 901. The first path selection circuit 900 performs calculations indicated by expressions 8, 10 and 12. The second path selection circuit 901 performs calculations indicated by expressions 14, 16 and 18.

Ten results of state transition selection output by the ACS circuit 5 (SEL012, SEL03, SEL112, SEL13, SEL2, SEL312, SEL33, SEL412, SEL43, SEL5) are input to the path memory circuit 6.

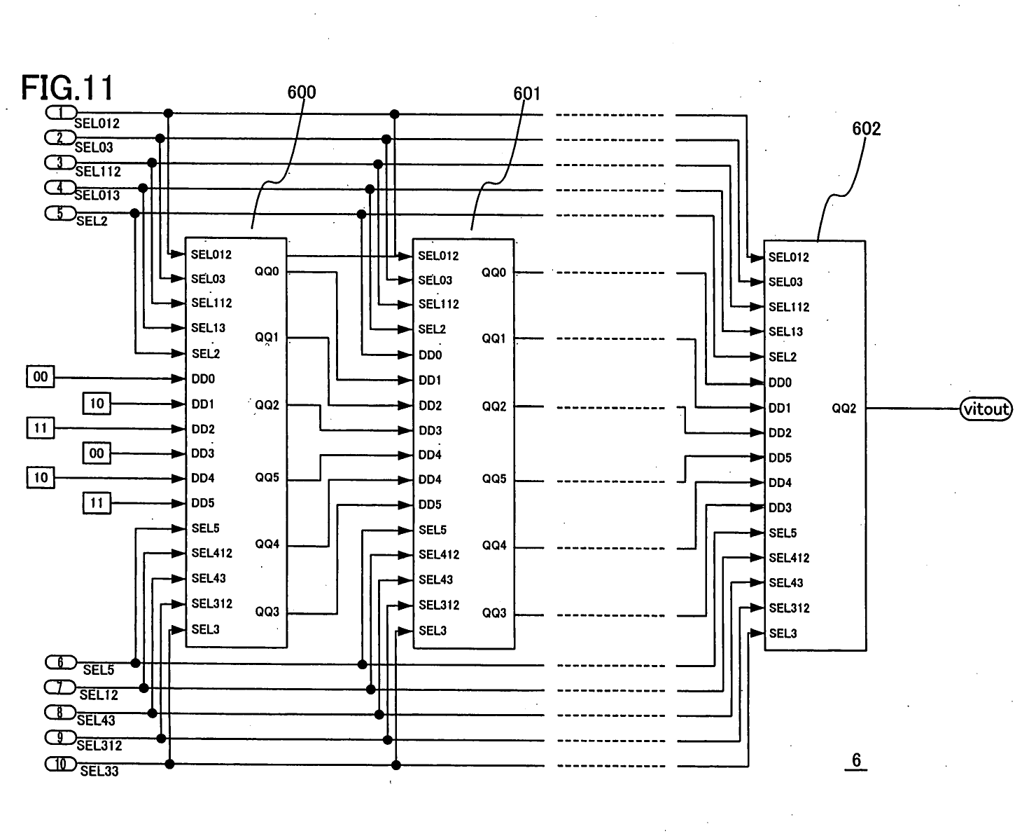

FIG. 11 shows a configuration of the path memory circuit 6.

The path memory circuit 6 comprises a sub-memory circuit 600, a sub-memory circuit 601, and a sub-memory circuit 602. The sub-memory circuits 600 to 602 are connected in series to one another. In this example, a calculation is performed once every two time points. Therefore, the number of required sub-memory circuit stages is ½ of that of a Viterbi circuit which performs a calculation at each channel clock count (i.e., every time point).

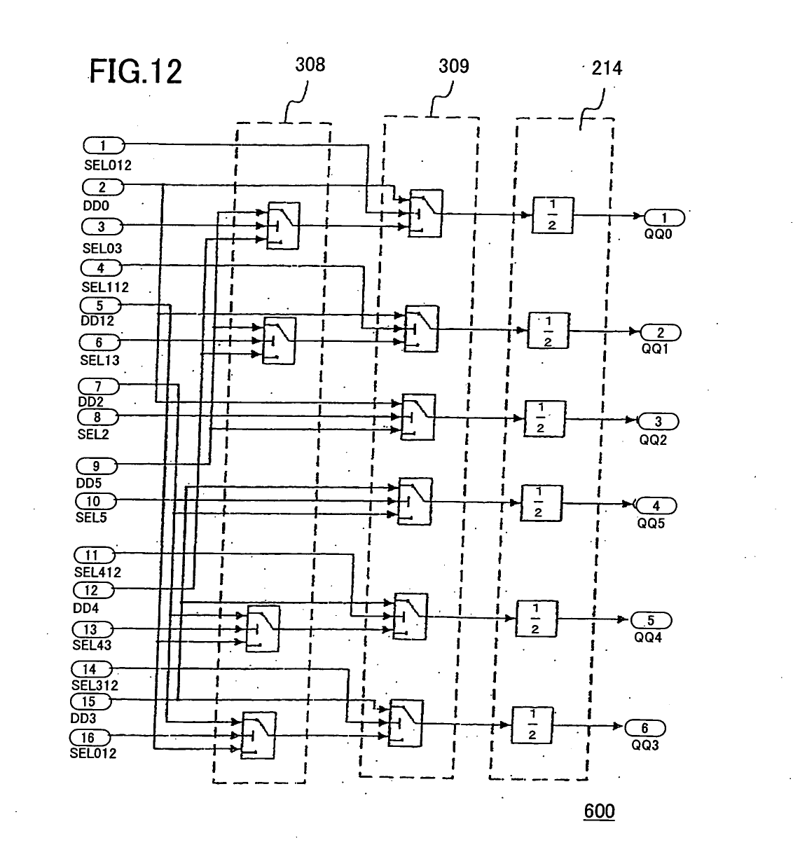

FIG. 12 shows a configuration of the sub-memory circuit 600.

A survival path is detected according to a result of state transition selection by the ACS circuit 5. According to the state transition rule, original digital information is output.

Hereinafter, an operation of the Viterbi circuit 19 will be described, in which a recorded code having a minimum polarity reversal interval of 2 and PR1221 equalization is used.

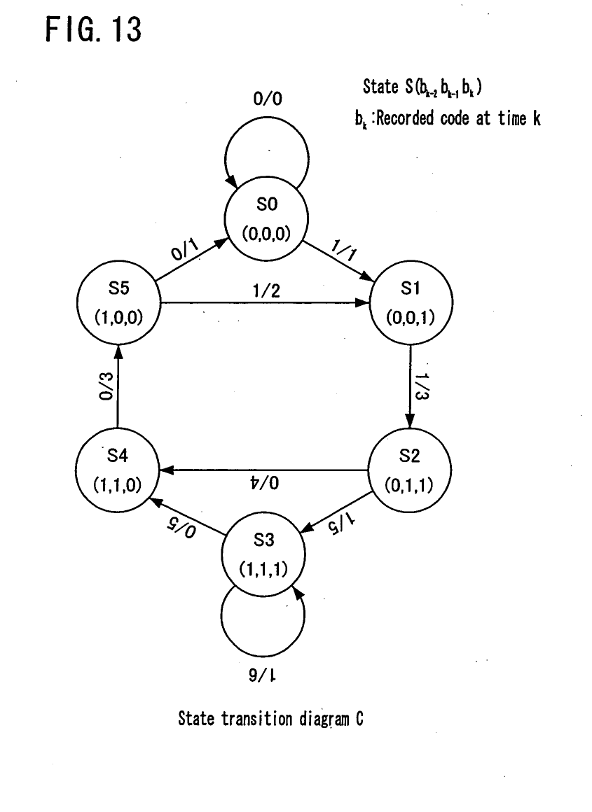

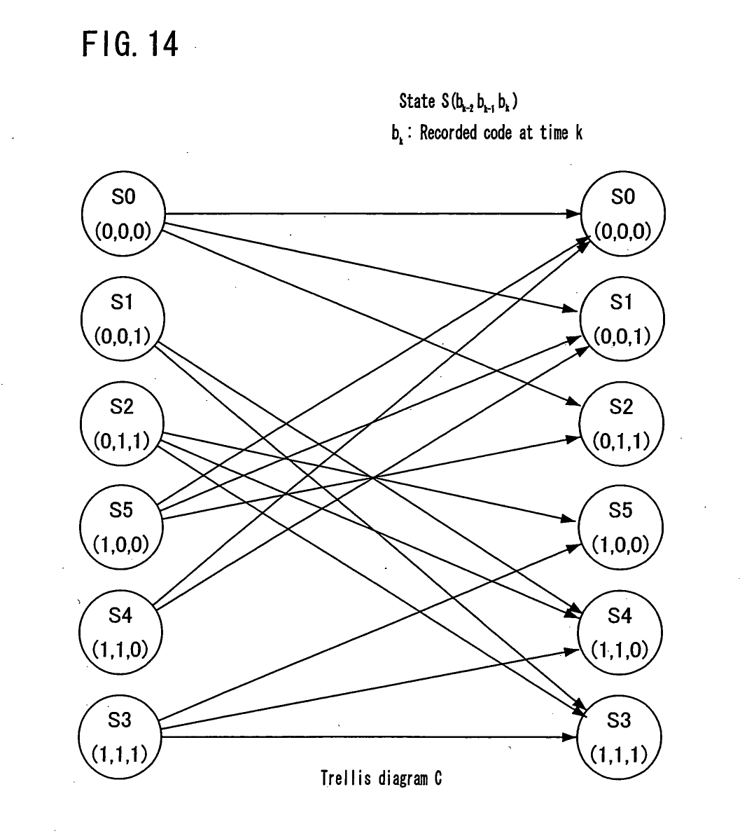

FIG. 13 shows a state transition diagram C obtained by applying PR1221 equalization to a recorded code having a minimum polarity reversal interval of 2. The state transition diagram C shows a state transition having six states and seven expected values.

Expression 3 calculates a plurality of path metric values (Lₖ^{S0}, Lₖ^{S1}, Lₖ^{S2}, Lₖ^{S3}, Lₖ^{S4}, Lₖ^{S5}).
Lₖ^{S0}=min[Lₖ₋₁^{S0}+(yₖ+3)², Lₖ₋₁^{S5}+(yₖ+2)²]
Lₖ^{S1}=min [Lₖₖ₋₁^{S0}+(yₖ+2)², Lₖ₋₁^{S5}+(yₖ+1)²]
Lₖ^{S2}=Lₖ₋₁^{S1}+(yₖ+0)²
Lₖ^{S3}=min[Lₖ₋₁^{S3}+(yₖ−3)², Lₖ₋₁^{S2}+(yₖ2)²]
Lₖ^{S4}=min[Lₖ₋₁^{S3}+(yₖ−2)², Lₖ₋₁^{S2}+(yₖ₋₁)²]
Lₖ^{S5}=Lₖ₋₁^{S4}+(yₖ+0) (Expression 3)

For the sake of simplicity, the branch metrics contained in expression 3 are multiplied by ½ and yₖ²/2 is subtracted from each resultant branch metric. In this case, expression 3 is changed to expression 4.
Lₖ^{S0}=min[Lₖ₋₁^{S0}+(yₖ+3)²/2−yₖ²/2, Lₖ₋₁^{S5}+(yₖ+2)²/2−yₖ²/2]
Lₖ^{S1}=min[Lₖ₋₁^{S0}+(yₖ+2)²/2−yₖ²/2, Lₖ₋₁^{S5}+(yₖ+1)²/2−yₖ²/2]
Lₖ^{S2}=Lₖ₋₁^{S1}+(yₖ+0)²/2−yₖ²/2
Lₖ^{S3}=min[Lₖ₋₁^{S3}+(yₖ−3)²/2−yₖ²/2, Lₖ₋₁^{S2}+(yₖ−2)²/2−yₖ²/2]
Lₖ^{S4}=min[Lₖ₋₁^{S3}+(yₖ−2)²/2−yₖ²/2, Lₖ₋₁^{S2}+(yₖ₋₁)²/2−yₖ²/2]
Lₖ^{S5}=Lₖ₋₁^{S4}+(yₖ+0)²/2−yₖ²/2 (Expression 4)

Expression 4 is expanded to obtain expression 5.
Lₖ^{S0}=min[Lₖ₋₁^{S0}+3yₖ+9/2, Lₖ₋₁^{S5}+2yₖ+2]
Lₖ^{S1}=min[Lₖ₋₁^{S0}+2yₖ+2, Lₖ₋₁^{S5}+yₖ+1/2]
Lₖ^{S2}=Lₖ₋₁^{S1}
Lₖ^{S3}=min[Lₖ₋₁^{S3}−3yₖ+9/2, Lₖ₋₁^{S2}−2yₖ+2]
Lₖ^{S4}=min[Lₖ₋₁^{S3}−2yₖ+2, Lₖ₋₁^{S2}−yₖ+1/2]
Lₖ^{S5}Lₖ₋₁^{S4} (Expression 4)

Branch metrics Aₖ to Gₖ are defined as described below.
Aₖ=3yₖ+9/2=(yₖ−thre4)+(yₖ−thre5)+(yₖ−thre6)
Bₖ=2yₖ+2=(yₖ−thre4)+(yₖ−thre5)
Cₖ=yₖ+1/2=(yₖ−thre4)
Dₖ=0
Eₖ=−yₖ+1/2=(thre3−yₖ)
Fₖ=−2yₖ+2=(thre3−yₖ)+(thre2−yₖ)
Gₖ=−3yₖ+9/2=(thre3−yₖ)+(thre2−yₖ)+(thre1−yₖ)

It is here assumed that thre1=5/2, thre2=3/2, thre3=1/2, thre4=−1/2, thre5=−3/2, and thre6=−5/2.

Based on expression 5 and the branch metrics Aₖ to Gₖ, expression 6 is obtained.
Lₖ^{S0}=min[Lₖ₋₁^{S0}+Aₖ, Lₖ₋₁^{S5}+Bₖ]
Lₖ^{S1}=min[Lₖ₋₁^{S0}+Bₖ, Lₖ₋₁^{S5}+Cₖ]
Lₖ^{S2}=Lₖ₋₁^{S1}
Lₖ^{S3}=min[Lₖ₋₁^{S3}+Gₖ, Lₖ₋₁^{S2}+Fₖ]
Lₖ^{S4}=min[Lₖ₋₁^{S3}+Fₖ, Lₖ₋₁^{S2}+Eₖ]
Lₖ^{S5}=Lₖ₋₁^{S4} (Expression 6)

FIG. 14 shows a trellis diagram C corresponding to the state transition diagram C of FIG. 13. The trellis diagram C can be obtained based on state transition from time k−2 to time k (two clock counts). Similarly, expression 6 can be changed to expression 7.
Lₖ^{S0}=min[min[Lₖ₋₂^{S0}+Aₖ₋₁, Lₖ₋₂^{S5}+Bₖ₋₁]+Aₖ, Lₖ₋₂^{S4}+Bₖ]
Lₖ^{S1}=min[min[Lₖ₋₂^{S0}+Aₖ₋₁, Lₖ₋₂^{S5}+Bₖ₋₁]+Bₖ, Lₖ₋₂^{S4}+Cₖ]
Lₖ^{S2}=min[Lₖ₋₂^{S0}+Bₖ₋₁Lₖ₋₂^{S5}+Cₖ₋₁]
Lₖ^{S3}=min[min[Lₖ₋₂^{S3}+Gₖ₋₁, Lₖ₋₂^{S2}+Fₖ₋₁]+Gₖ, Lₖ₋₂^{S1}+Fₖ]
Lₖ^{S4}=min[min[Lₖ₋₂^{S3}+Gₖ₋₁, Lₖ₋₂^{S2}+Fₖ₋₁]+Fₖ, Lₖ₋₂^{S1}+Eₖ]
Lₖ^{S5}=min[Lₖ₋₂^{S3}+Fₖ₋₁, Lₖ₋₂^{S2}+Eₖ₋₁] (Expression 7)

Regarding Lₖ^{S0}, the following inequalities 8-1 to 8-3 are derived from the above-described expression.
Aₖ₋₁+Lₖ₋₂^{S0}<Lₖ₋₂^{S5}+Bₖ₋₁ (Expression 8-1)
Aₖ₋₁+Aₖ+Lₖ₋₂^{S0}<Lₖ₋₂^{S4}+Bₖ (Expression 8-2)
Lₖ₋₂^{S5}+Bₖ₋₁+Aₖ<Lₖ₋₂^{S4}+Bₖ (Expression 8-3)
p It is assumed that if expression 8-1 is true, signal SEL01=‘1’; if expression 8-2 is true, signal SEL02=‘1’; and if expression 8-3 is true, signal SEL03=‘1’. In this case, expression 9 can be derived regarding Lₖ^{S0} contained in expression 7.

If SEL01=‘1’ and SEL02=‘1’ is true,
Lₖ^{S0}=Lₖ₋₂^{S0}+Aₖ₋₁+Aₖ (Expression 9)

If SEL01=‘1’ and SEL02=‘1’ is false and SEL03=‘1’ is true,
Lₖ^{S0}=Lₖ₋₂^{S5}+Bₖ₋₁+Aₖ

If otherwise,
Lₖ^{S0}=Lₖ₋₂+Bₖ

The following inequalities 10-1 to 10-3 can be derived regarding Lₖ^{S1}.
Aₖ₋₁+Lₖ₋₂^{S0}<Lₖ₋₂^{S5}+Bₖ₋₁ (Expression 10-1)
Aₖ₋₁+Bₖ+Lₖ₋₂^{S0}<Lₖ₋₂^{S4}Cₖ (Expression 10-2)
Lₖ₋₂^{S5}+Bₖ₋₁+Bₖ<Lₖ₋₂^{S4}+Cₖ (Expression 10-3)

It is assumed that if expression 10-1 is true, signal SEL01=‘1’; if expression 10-2 is true, signal SEL12=‘1’; and if expression 10-3 is true, signal SEL13=‘1’. In this case, the following expression 11 can be derived regarding Lₖ^{S1} contained in expression 7.

If SEL01=‘1’ and SEL12=‘1’ is true,
Lₖ^{S1}=Lₖ₋₂^{S0}+Aₖ₋₁+Bₖ (Expression 11)

If SEL01=‘1’ and SEL12=‘1’ is false and SEL13=‘1’ is true,
Lₖ^{S1}=Lₖ₋₂^{S5}+Bₖ₋₁+Bₖ

If otherwise,
Lₖ^{S1}=Lₖ₋₂^{S4}+Cₖ

The following inequality 12 can be derived regarding Lₖ^{S2}.
Lₖ₋₂^{S0}+Bₖ₋₁<Lₖ₋₂^{S5}+Cₖ₋₁ (Expression 12)

It is assumed that if expression 12 is true, signal SEL2=‘1’. In this case, the following expression 13 can be derived regarding Lₖ^{S2} contained in expression 7.

If SEL2=‘1’ is true,
Lₖ^{S2}=Lₖ₋₂^{S0}+Bₖ₋₁ (Expression 13)

If SEL2=‘0’ is true,
Lₖ^{S2}=Lₖ₋₂^{S5}+Cₖ₋₁

The following inequalities 14-1 to 14-3 can be derived regarding Lₖ^{S3}.
Lₖ₋₂^{S3}+Gₖ₋₁<Lₖ₋₁^{S2}+Fₖ₋₁ (Expression 14-1)
Lₖ₋₂^{S3}+Gₖ₋₁+Gₖ<Lₖ₋₂^{S1}+Fₖ (Expression 14-2)
Lₖ₋₂^{S2}+Fₖ₋₁+Gₖ<Lₖ₋₂^{S1}+Fₖ (Expression 14-3)

It is assumed that if expression 14-1 is true, signal SEL31=‘1’; if expression 14-2 is true, signal SEL32=‘1’; and if expression 14-3 is true, signal SEL33=‘1’. In this case, the following expression can be derived regarding Lₖ^{S3} contained in expression 7.

If SEL31=‘1’ and SEL32=‘1’ is true,
Lₖ^{S3}=Lₖ₋₂^{S3}+Gₖ₋₁+Gₖ (Expression 15)

If SEL31=‘1’ and SEL32=‘1’ is false and SEL33=‘1’ is true,
Lₖ^{S3}=Lₖ₋₂^{S2}+Fₖ₋₁+Gₖ

If otherwise,
Lₖ^{S3}=Lₖ₋₂^{S1}+Fₖ

The following inequalities 16-1 to 16-3 can be derived regarding Lₖ^{S4}.
Lₖ₋₁^{S3}+Gₖ₋₁<Lₖ₋₂^{S2}+Fₖ₋₁ (Expression 16-1)
Lₖ₋₂^{S3}+Gₖ₋₁+Fₖ<Lₖ₋₂^{S1}+Eₖ (Expression 16-2)
Lₖ₋₂^{S2}+Fₖ₋₁+Fₖ<Lₖ₋₂^{S1}+Eₖ (Expression 16-3)

It is assumed that if expression 16-1 is true, signal SEL31=‘1’; if expression 16-2 is true, signal SEL42=‘1’; and if expression 16-3 is true, signal SEL43=‘1’. In this case, the following expression can be derived regarding Lₖ^{S4} contained in expression 7.

If SEL31=‘1’ and SEL42=‘1’ is true,
Lₖ^{S4}=Lₖ₋₂^{S3}+Gₖ₋₁+Fₖ (Expression 17)

If SEL31=‘1’ and SEL42=‘1’ is false and SEL43=‘1’ is true,
Lₖ^{S4}=Lₖ₋₂^{S2}+Fₖ₋₁+Fₖ

If otherwise,
Lₖ^{S4}=Lₖ₋₂^{S1}+Eₖ

Finally, the following expression can be derived regarding Lₖ^{S5}.
Lₖ₋₂^{S3}+Fₖ₋₁<Lₖ₋₂^{S2}+Eₖ₋₁ (Expression 18)

It is assumed that if expression 18 is true, signal SEL5=‘1’. In this case, the following expression can be derived regarding Lₖ^{S5} contained in expression 7.

If SEL5=‘1’ is true,
Lₖ^{S5}=Lₖ₋₂^{S3}+Fₖ₋₁ (Expression 19)

If SEL5=‘0’ is true,
Lₖ^{S5}=Lₖ₋₂^{S2}+Eₖ₋₁

Hereinafter, an operation of the Viterbi circuit 19 will be described, where a recorded code having a minimum polarity reversal interval of 3 and PR3443 equalization are used.

According to expression 20, a plurality of path metric values (Lₖ^{S0}, Lₖ^{S1}, Lₖ^{S2}, Lₖ^{S3}, Lₖ^{S4}, Lₖ^{S5}) are calculated.
Lₖ^{S0}=min[Lₖ₋₁^{S0}+(yₖ+7)², Lₖ₋₁^{S5}+(yₖ+4)²]
Lₖ^{S1}=Lₖ₋₁^{S0}+(yₖ+4)²
Lₖ^{S2}=Lₖ₋₁^{S1}+(yₖ+0)²
Lₖ^{S3}=min[Lₖ₋₁^{S3}+(yₖ−7)², Lₖ₋₁^{S2}+(yₖ−4)²]
Lₖ^{S4}=Lₖ₋₁^{S3}+(yₖ−4)²
Lₖ^{S5}=Lₖ₋₁^{S4}+(yₖ+0)² (Expression 20)

For the sake of simplicity, yₖ² is subtracted from the branch metric terms contained in expression 20, and the resultant branch metric terms are multiplied by ⅛. As a result, expression 20 is changed to the following expression 21.
Lₖ^{S0}=min[Lₖ₋₁^{S0}+(yₖ+7)²/8−(yₖ+0)²/8, Lₖ₋₁^{S5}+(yₖ+4)²/8−(yₖ+0)²/8]
Lₖ^{S1}=Lₖ₋₁^{S0}+(yₖ+4)²/8−(yₖ+0)²/8
Lₖ^{S2}=Lₖ₋₁^{S1}
Lₖ^{S3}=min[Lₖ₋₁^{S3}+(yₖ−7)²/8−(yₖ+0)²/8, Lₖ₋₁^{S2}+(yₖ−4)²/8−(yₖ+0)²/8]
Lₖ^{S4}=Lₖ₋₁^{S3}+(yₖ−4)²/8−(yₖ+0)²/8
Lₖ^{S5}=Lₖ₋₁^{S4} (Expression 21)

Branch metrics Aₖ to Gₖ are defined as follows. In this case, expression 22 is obtained based on expression 21 and the branch metrics Aₖ to Gₖ.
Lₖ^{S0}=min[min[Lₖ₋₂^{S0}+Aₖ₋₁, Aₖ₋₁, Lₖ₋₂^{S5}+Bₖ₋₁]+Aₖ, Lₖ₋₂^{S4}+Bₖ]
Lₖ^{S1}=min[Lₖ₋₂^{S0}+Aₖ₋₁, Lₖ₋₂^{S5}+Bₖ₋₁]+Bₖ
Lₖ^{S2}=Lₖ₋₂^{S0}+Bₖ₋₁
Lₖ^{S3}=min[Lₖ₋₂^{S1}+Fₖ, min[Lₖ₋₂^{S2}+Fₖ₋₁, Lₖ₋₂^{S3}+Gₖ₋₁]+Gₖ]
Lₖ^{S4}=min[Lₖ₋₂^{S2}+Fₖ₋₁, Lₖ₋₂^{S3}+Gₖ₋₁]+Fₖ
Lₖ^{S5}=Lₖ₋₂^{S3}+Fₖ₋₁ (Expression 22)
Aₖ=((yₖ+7)²−(yₖ+0)²)/8=3(yₖ−THRED)/4+(yₖ−THREC)
Bₖ=((yₖ+4)²−(yₖ+0)²)/8=(yₖ−THREC)
Fₖ=((yₖ−4)²−(yₖ+0)²)/8=(THREB−yₖ)
Gₖ=((yₖ−7)²−(yₖ+0)²)/8=3(THREA−yₖ)/4+(THREB−yₖ)
THREA=(7+4)/2
THREB=−4/2
THREC=−4/2
THRED=(−7−4)/2

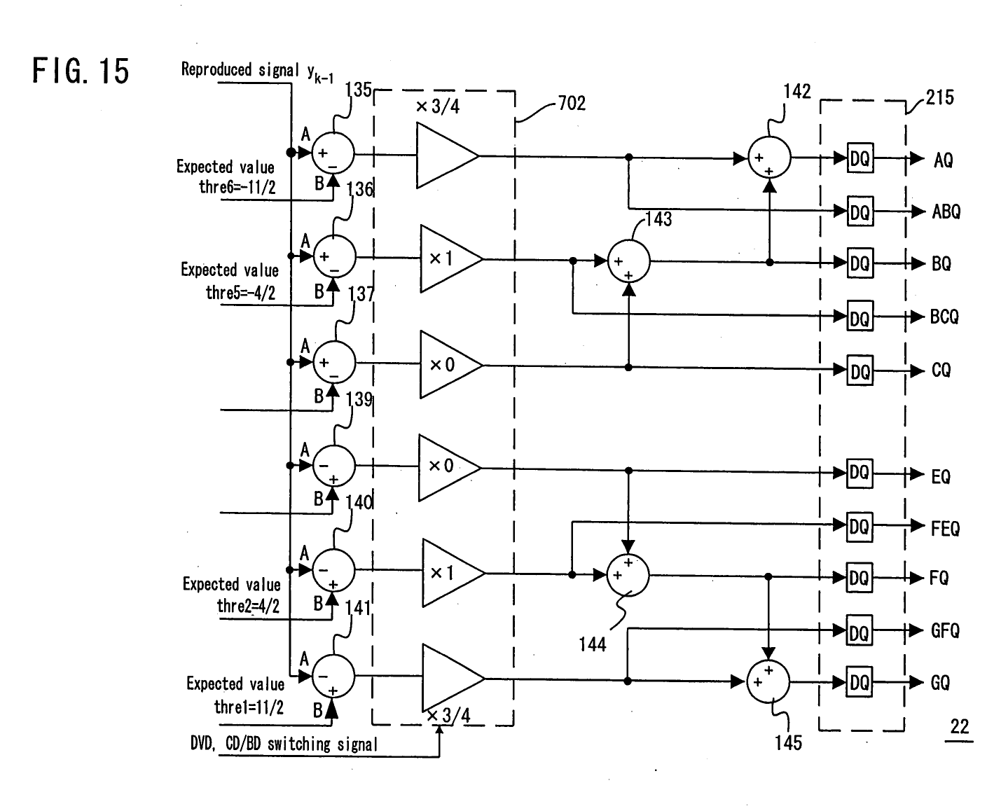

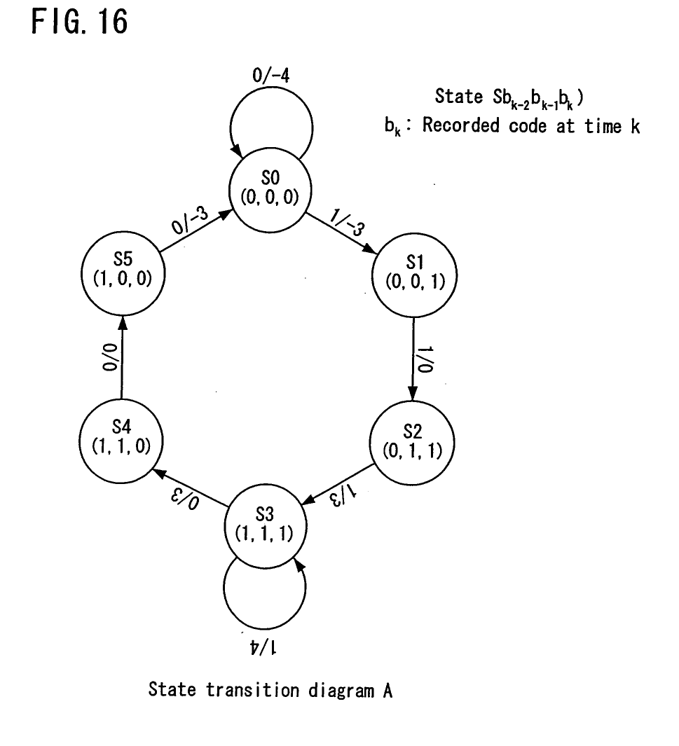

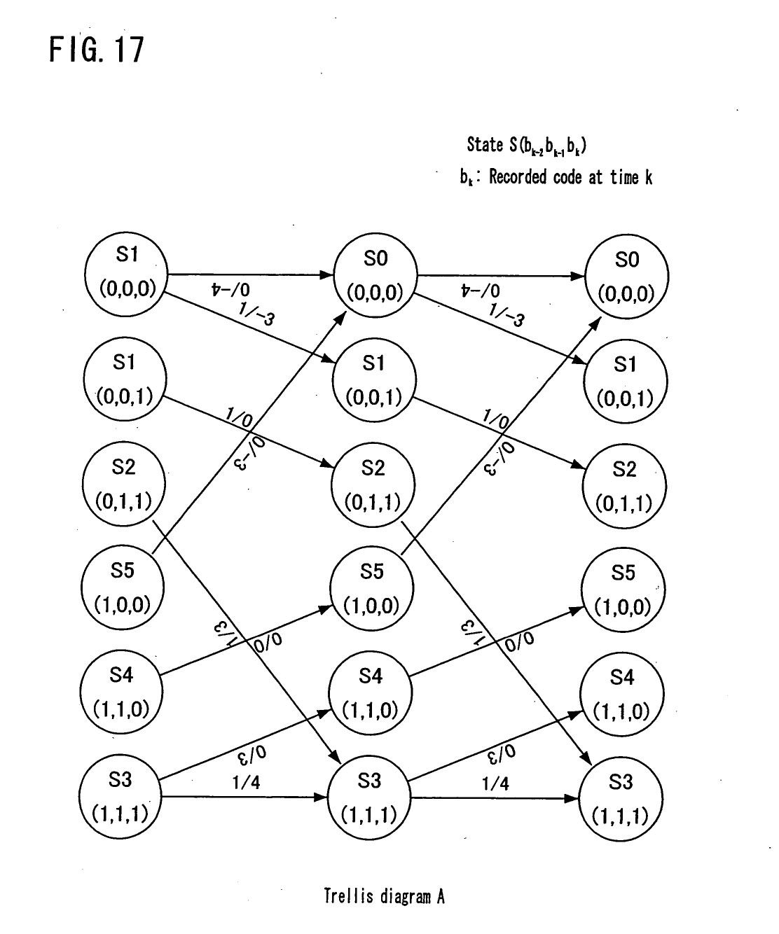

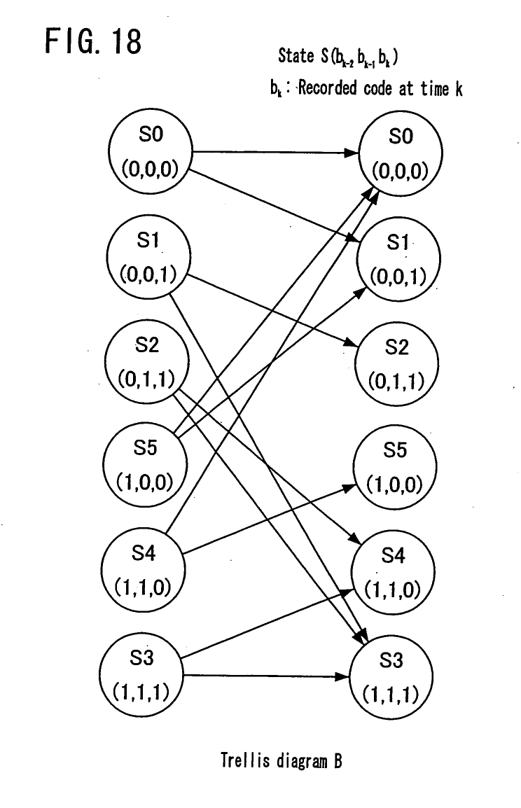

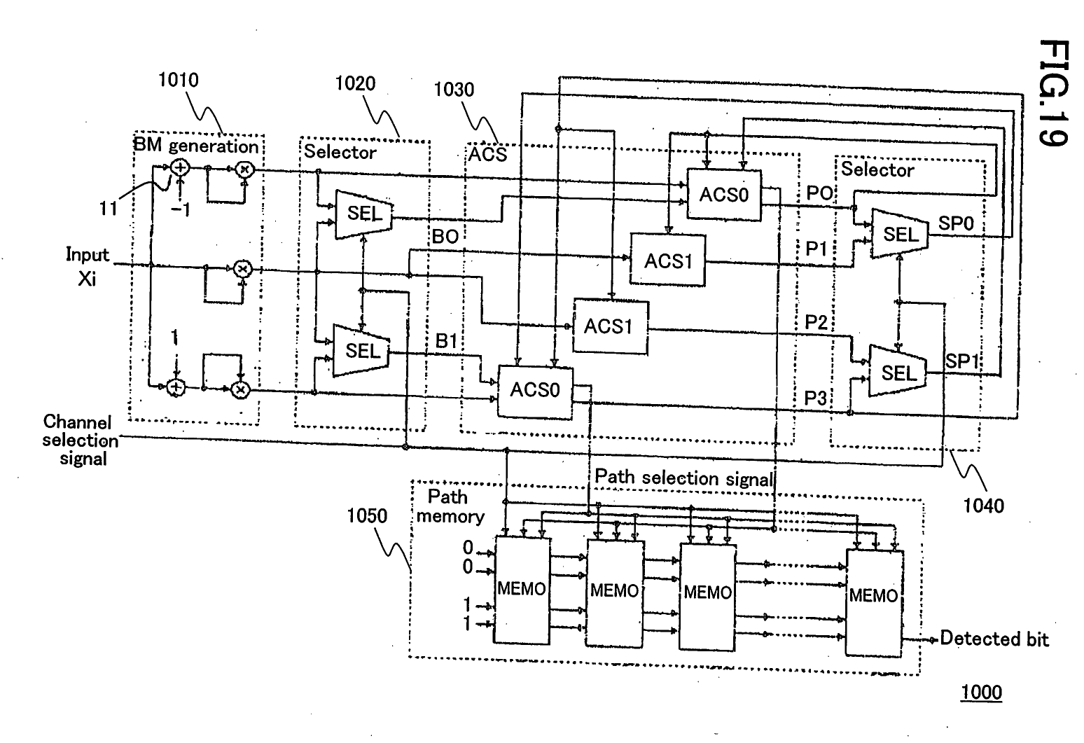

FIG. 15 shows a configuration of a sub-branch metric calculation circuit 22. The sub-branch metric calculation circuit 22 comprises subtractors 135 to 141, a coefficient setting block 702, adders 142 to 145, and a block 215.

Each of the subtractors 135 to 141 receives a reproduced signal yₖ₋₁ and an expected value indicating an expected value signal. Each of the subtractors 135 to 141 generates a difference value between a reproduced value indicated by the reproduced signal yₖ₋₁ and the expected value.

The coefficient setting block 702 multiplies the difference value by a constant. The constant is determined based on a DVD, CD/BD switching signal.

By changing a value of the coefficient setting block 702 based on the DVD, CD/BD switching signal (gain switching signal), the sub-branch metric calculation circuit 2 can be changed to the sub-branch metric calculation circuit 22. For example, in order to calculate a branch metric adaptable to PR3443 equalization, the value of the coefficient setting block 702 is only changed based on the DVD, CD/BD switching signal (gain switching signal) when the difference value between the reproduced signal and the expected value is multiplied by a constant.

The operational expression (expression 7) of path metric when a recorded code having a reversal interval of 2 and PR1221 equalization are used, is compared with the operational expression (expression 22) of path metric when a recorded code having a reversal interval of 3 and PR3443 equalization are used. A difference is that the number of state transitions is smaller by four. The circuit is switched so that these four state transitions are not selected.

Specifically, the results of the state transition selection (SEL112, SEL13, SEL2, SEL312, SEL412, SEL43 and SEL5 in FIG. 10) are changed. Selectors 306 and 307 are set so that the same signal as that of SEL01 is output to SEL112, the same signal as that of SEL31 is output to SE-L412, and ‘1’ is consistently output to SEL13, SEL2, SEL43 and SEL5.

As described above, by adding a small circuit(s) to the branch metric calculation circuit 1 and the ACS circuit 5, a Viterbi circuit compatible with different state transition rules can be achieved.

In the example described with reference to FIGS. 1 to 3, the optical head 11 corresponds to a “section constructed to be able to access a plurality of recording media having a plurality of types”. The Viterbi circuit 19 corresponds to a “maximum likelihood encoding section constructed to be compatible with a plurality of signals reproduced from a plurality of recording media having a plurality of types”. The branch metric calculation circuit 1 corresponds to a “branch metric value generation section for generating a plurality of branch metric values corresponding to a type of recording medium based on a type signal indicating a type”. The ACS circuit 5 corresponds to a “path metric value generation section for generating a plurality of path metric values corresponding to a type of recording medium based on a type signal indicating the type”. The path memory circuit 6 corresponds to a “path memory section for detecting digital information from a signal reproduced from a type of recording medium based on a plurality of path metric values”. However, the digital information reproduction apparatus of the present invention is not limited to that shown in FIG. 1. A reproduction apparatus having any configuration may fall within the scope of the present invention as long as the function of each section can be achieved.

In the above-described embodiment of the present invention, the type signal (DVD, CD/BD switching signal) indicates either that the type of a recording medium is DVD or CD or that the type of a recording medium is BD (Blu-ray Disc). However, the type of a recording medium indicated by the type signal is not limited to these types. For example, the type of a recording medium includes at least one of DVD-R, DVD-RW, CD-R, and CD-RW. Alternatively, the type of a recording medium includes at least one of a recording medium in which a signal is recorded by 8-16 modulation, a recording medium in which a signal is recorded by (1, 7) modulation, and a recording medium in which a signal is recorded by other modulation techniques.

For example, a type signal is generated by the user, who has recognized the type of a recording medium, causing an apparatus to recognize the type of the recording medium (e.g., the user pushes a button provided on the reproduction apparatus). Alternatively, the access section may generate a type signal based on a result of accessing a recording medium (e.g., when a signal indicating the type of a recording medium is previously recorded in the recording medium). Alternatively, a type signal may be generated based on the shape of a recording medium cartridge.

For example, the Viterbi circuit 19 may be a maximum likelihood encoding circuit as long as maximum likelihood encoding can be achieved for a signal reproduced from a recording medium.

For example, the Viterbi circuit 19 may be fabricated as a part or the whole of a one-chip LSI (semiconductor integrated circuit). When the Viterbi circuit 19 is fabricated as a one-chip LSI, the production process of the digital information reproduction apparatus 20 can be simplified.

Further, each section included in the digital information reproduction apparatus 20 of the embodiment of the present invention may be implemented as hardware or software or in combination thereof. In either case, the digital information reproduction apparatus 20 may perform maximum likelihood encoding of the present invention including “generating a plurality of branch metric values corresponding to a type of recording medium based on a type signal indicating a type”, “generating a plurality of path metric values corresponding to a type of recording medium based on a type signal indicating a type,” detecting digital information from a signal reproduced from a type of recording medium based on a plurality of path metric values”. The maximum likelihood encoding of the present invention may have any procedure as long as each of the above-described steps can be performed.

For example, the digital information reproduction apparatus 20 of the present invention may store a maximum likelihood encoding program for executing the function of a maximum likelihood encoding apparatus.

The maximum likelihood encoding program may be previously stored in a storage section included in the digital information reproduction apparatus when a computer is shipped. Alternatively, after shipment of a computer, the maximum likelihood encoding program may be stored into the storage section. For example, the user may download the maximum likelihood encoding program from a website on the Internet with or without payment, and installs the downloaded program in a computer. When the maximum likelihood encoding program is recorded on a computer readable recording medium, such as a flexible disc, a CD-ROM, a DVD-ROM or the like, an input device (e.g., a disc drive device) may be used to install the maximum likelihood encoding program into a computer. The installed maximum likelihood encoding program is stored in a storage section.

The digital information reproduction apparatus of the present invention is operated at 1/n the frequency of a channel clock. The digital information reproduction apparatus has a Viterbi circuit which achieves a branch metric calculation only by addition and subtraction. By switching portions of the circuit, different formats can be handled. The digital information reproduction apparatus is also useful for a binary circuit for communication devices and the like.

Although certain preferred embodiments have been described herein, it is not intended that such embodiments be construed as limitations on the scope of the invention except as set forth in the appended claims. Various other modifications and equivalents will be apparent to and can be readily made by those skilled in the art, after reading the description herein, without departing from the scope and spirit of this invention. All patents, published patent applications and publications cited herein are incorporated by reference as if set forth fully herein.

1. A maximum likelihood encoding apparatus constructed to be compatible with a plurality of signals reproduced from a plurality of recording media having a plurality of types, comprising:
a path metric value generation section for generating a plurality of path metric values corresponding to a recording medium having one of the plurality of types based on a type signal indicating the one of the plurality of types; and
a path memory section for detecting digital information from a signal reproduced from the recording medium having the one of the plurality of types based on the plurality of path metric values.

2. A maximum likelihood encoding apparatus according to claim 1, wherein the path metric value generation section generates a plurality of path metric values at current time k based on a plurality of path metric values at time k-n where k is an integer and n is an integer of 1 or more.

3. A maximum likelihood encoding apparatus according to claim 1, further comprising a branch metric value generation section for generating a plurality of branch metric values from an expected value signal indicating an expected value and the signal reproduced from the recording medium having the one of the plurality of types, wherein the path metric value generation section generates the plurality of path metric values based on the plurality of branch metric values and the type signal.

4. A maximum likelihood encoding apparatus according to claim 3, wherein
the expected value signal is determined based on PR equalization characteristics, and
the branch metric value generation section comprises:
a difference value generation section for generating a difference value between the expected value and a reproduced value indicated by the signal reproduced from the recording medium having the one of the plurality of types; and
a section for multiplying the difference value by a constant.

5. A maximum likelihood encoding apparatus according to claim 1, wherein the signal reproduced from the recording medium having the one of the plurality of types is subjected to maximum likelihood encoding by PR equalization satisfying:
h((2k−1)T/2)=a (k=−1)
h((2k−1)T/2)=b (k=0)
h((2k−1)T/2)=b (k=1)
h((2k−1)T/2)=a (k=2)
h((2k−1)T/2)=0 (k≠−1, 0, 1, 2)
where h(t) indicates an impulse response of a recording/reproduction system, a and b indicate arbitrary constants, and T indicates a cycle of a timing signal, and
the type signal indicates one of a type having a minimum polarity reversal interval of 2 and a type having a minimum polarity reversal interval of 3.

6. A maximum likelihood encoding apparatus constructed to be compatible with a plurality of signals reproduced from a plurality of recording media having a plurality of types, comprising:
a branch metric value generation section for generating a plurality of branch metric values corresponding to a recording medium having one of the plurality of types based on a type signal indicating the one of the plurality of types; and
a branch memory section for detecting digital information from a signal reproduced from the recording medium having the one of the plurality of types based on the plurality of branch metric values.

7. A maximum likelihood encoding apparatus according to claim 6, wherein the branch metric value generation section generates a plurality of branch metric values at current time k based on a plurality of path metric values at time k-n where k is an integer and n is an integer of 1 or more.

8. A maximum likelihood encoding apparatus according to claim 6, wherein
the branch metric value generation section generates the plurality of branch metric values based on an expected value signal indicating an expected value and the recording medium having the one of the plurality of types, and
the maximum likelihood encoding apparatus further comprises a path metric value generation section for generating a plurality of path metric values based on the plurality of branch metric values and the type signal.

9. A maximum likelihood encoding apparatus according to claim 8, wherein
the expected value signal is determined based on PR equalization characteristics, and
the branch metric value generation section comprises:
a difference value generation section for generating a difference value between the expected value and a reproduced value indicated by the signal reproduced from the recording medium having the one of the plurality of types; and
a section for multiplying the difference value by a constant.

10. A maximum likelihood encoding apparatus according to claim 6, wherein the signal reproduced from the recording medium having the one of the plurality of types is subjected to maximum likelihood encoding by PR equalization satisfying:
h((2k−1)T/2)=a (k=−1)
h((2k−1)T/2)=b (k=0)
h((2k−1)T/2)=b (k=1)
h((2k−1)T/2)=a (k=2)
h((2k−1)T/2)=0 (k≠−1, 0, 1, 2)
where h(t) indicates an impulse response of a recording/reproduction system, a and b indicate arbitrary constants, and T indicates a cycle of a timing signal, and when one of the plurality of types has a minimum polarity reversal interval of 2, a=1 and b=2, and when another of the plurality of types has a minimum polarity reversal interval of 3, a=3 and b=4.

11. A maximum likelihood encoding method, wherein an apparatus constructed to be compatible with a plurality of signals reproduced from a plurality of recording media having a plurality of types, is used for maximum likelihood encoding of the plurality of reproduced signals, the method comprising:
generating a plurality of path metric values corresponding to a recording medium having one of the plurality of types based on a type signal indicating the one of the plurality of types; and
detecting digital information from a signal reproduced from the recording medium having the one of the plurality of types based on the plurality of path metric values.

12. A maximum likelihood encoding method, wherein an apparatus constructed to be compatible with a plurality of signals reproduced from a plurality of recording media having a plurality of types, is used for maximum likelihood encoding of the plurality of reproduced signals, the method comprising:
generating a plurality of branch metric values corresponding to a recording medium having one of the plurality of types based on a type signal indicating the one of the plurality of types; and
detecting digital information from a signal reproduced from the recording medium having the one of the plurality of types based on the plurality of branch metric values.

13. A program for causing an apparatus constructed to be compatible with a plurality of signals reproduced from a plurality of recording media having a plurality of types to perform a maximum likelihood encoding process for maximum likelihood encoding of the plurality of reproduced signals, the maximum likelihood encoding process comprising:
generating a plurality of path metric values corresponding to a recording medium having one of the plurality of types based on a type signal indicating the one of the plurality of types; and
detecting digital information from a signal reproduced from the recording medium having the one of the plurality of types based on the plurality of path metric values.

14. A program for causing an apparatus constructed to be compatible with a plurality of signals reproduced from a plurality of recording media having a plurality of types to perform a maximum likelihood encoding process for maximum likelihood encoding of the plurality of reproduced signals-, the maximum likelihood encoding process comprising:
generating a plurality of branch metric values corresponding to a recording medium having one of the plurality of types based on a type signal indicating the one of the plurality of types; and
detecting digital information from a signal reproduced from the recording medium having the one of the plurality of types based on the plurality of branch metric values.

15. A reproduction apparatus, comprising:
an access section constructed to be able to access a plurality of recording media having a plurality of types; and
a maximum likelihood encoding section constructed to be compatible with a plurality of signals reproduced from the plurality of recording media having the plurality of types,
wherein the maximum likelihood encoding section comprises:
a path metric value generation section for generating a plurality of path metric values corresponding to a recording medium having one of the plurality of types based on a type signal indicating the one of the plurality of types; and
a path memory section for detecting digital information from a signal reproduced from the recording medium having the one of the plurality of types based on the plurality of path metric values.

15. A reproduction apparatus, comprising:
an access section constructed to be able to access a plurality of recording media having a plurality of types; and
a maximum likelihood encoding section constructed to be compatible with a plurality of signals reproduced from the plurality of recording media having the plurality of types,
wherein the maximum likelihood encoding section comprises:
a path metric value generation section for generating a plurality of branch metric values corresponding to a recording medium having one of the plurality of types based on a type signal indicating the one of the plurality of types; and
a path memory section for detecting digital information from a signal reproduced from the recording medium having the one of the plurality of types based on the plurality of branch metric values.
